(19) United States
(12) Patent Application Publication
(10) Pub. No.: US 2007/0087470 A1
(43) Pub. Date: Apr. 19, 2007

(54) Vapor phase synthesis of metal and metal oxide nanowires

(76) Inventors: Mahendra Kumar Sunkara, Louisville, KY (US); Sreeram Vaddiraju, Cambridge, MA (US); Biswapriya Deb, Louisville, KY (US); Jyothish Thangala, Louisville, KY (US)

Correspondence Address: David W. Carrithers;CARRITHERS LAW OFFICE, PLLC, One Paragon Centre, 6060 Dutchman's Lane, Suite 140, Louisville, KY, 40205, US

(21) Appl. No.: 11/540,913

(22) Filed: Sep. 29, 2006

Related U.S. Application Data
(60) Provisional application No. 60/722,803, filed on Sep. 30, 2005.
(60) Provisional application No. 60/840,991, filed on Aug. 30, 2006.

(51) Int. Cl. H01L 51/40; H01L 21/44

(52) U.S. Cl. 438/99; 438/683; 977/811

(57) ABSTRACT

Vapor phase methods for synthesizing metal nanowires directly without the help of templates. A vapor phase method in which nucleation and growth of metal oxides at temperatures higher than the oxide decomposition temperatures lead to the respective metal nanowires. The chemical vapor transport of tungsten in the presence of oxygen onto substrates kept at temperatures higher than the tungsten oxide decomposition temperature (˜1450° C.) led to nucleation and growth of pure metallic tungsten nanowires. In a similar procedure, tungsten oxide nanowires were synthesized by maintaining the substrates at a temperature lower than the decomposition temperature of tungsten oxide. The vapor transport of low-melting metal oxides provides a procedure for synthesizing metal and metal oxide nanowires.

This application claims priority from U.S. Provisional Application Ser. No. 60/722, 803 filed on Sep. 30, 2005 and U.S. Provisional Application Ser. No. 60/840,991 filed on Aug. 30, 2006 both of which are incorporated by reference herein.

This application is part of a government project. The research leading to this invention was supported by NSF through CAREER grant (CTS 9876321) and United States Air Force grant AFOSR (F49620-00-1-0310). The United States Government retains certain rights in this invention.

### BACKGROUND OF THE INVENTION

1. Field of the Invention

The invention relates to the field of providing a vapor transport synthesis method of forming low-melting metal and metal oxide nanowires of transition metals without the help of templates and method of bulk synthesis of same. Nanowires of transition metals have applications in electronic devices, sensors, and magnetic recording devices and show interesting structural and electronic characteristics.

2. Description of the Prior Art

The vapor transport of low-melting oxides is a known procedure for metal oxide-ribbons, whiskers, and recently for nanobelts. Recently, there are also two reports with one using hydrogen on tungsten complexed organic precursors for amorphous carbon sheathed, polycrystalline tungsten nanowires. The first report by Y. B. Li, Y. Bando, D. Golberg, and K. Kurashima for “WO₃ Nanorods/Nanobelts Synthesized via Physical Vapor Deposition Process” was printed in Appl. Phys. Let. Vol. 81, page 745, (2002). The second report by J. Thong, T. Lui, and C. H. Oon was printed in Appl. Phys. Lett at Vol. 81, page 4823, (2002). Vapor phase methods for synthesizing metal nanowires directly without the help of templates have not been studied extensively.

Vapor phase methods for synthesizing metal nanowires directly without the help of templates have not been studied extensively. Even though there have been few reports with one dating back to 1877 on metal whisker synthesis from the vapor phase, the inconclusive growth mechanism did not lead to any serious developments for nanowires. Recently, there are also two reports with one using hydrogen on tungsten complexed organic precursors for amorphous carbon sheathed polycrystalline tungsten nanowires.

### SUMMARY OF THE INVENTION

The invention provides a novel vapor phase concept for the synthesis of metal and metal oxide nanowires of metals without the use of any catalysts, especially refractory and transistion metals. Chemical vapor phase transport and nucleation of metal oxides onto substrates maintained at a temperature anywhere from 450°-1200 ° C. leads to the formation of the respective metal oxides. Similar chemical vapor transport process onto substrates kept at temperatures higher than the respective decomposition temperatures produces metal nanowires. In the absence of any reducing gas phase species, the substrate temperature will need to greater than 1300° C. and less than 2000° C. In the presence of hydrogen or water vapor or hydroxide species, the substrate temperature could be anywhere from 100 ° C.-1000° C. for producing metal nanowires. The diameter of the nanowires can be controlled using temperature and other process variables as parameters. The present invention provides a means for producing nanowires at temperatures as low as 100° C. by using hydrogen along with oxygen.

Moreover, the invention provides for a method of synthesizing bulk quantities of oxide nanostructures of non-catalytic, low melting metals, comprising the steps of exposing molten non-catalytic, low melting metals to an activated gas phase, for example plasma, containing an appropriate mixture of oxygen and hydrogen radicals. A high density of nuclei occurs that grow in one dimension directly there from creating highly crystalline metal oxide nanowires devoid of any structural defects having thicknesses in a range from 20 to 100 nm and lengths in range from ten to a thousand microns long. The crystalline metal oxide nanostructures comprise tungsten oxide tubes and nanowires.

More particularly the present invention provides a method of synthesizing oxide nanostructures of non-catalytic low melting metals, comprising the chemical vapor transport of oxide or halide or metalorganic vapor phase species using either liquid or gas or solid sources onto substrates kept at temperatures lower than the decomposition temperatures of the respective oxides and forming a high density of nuclei that grow in one dimension directly creating highly crystalline metal oxide nanowires devoid of any structural defects and having diameters in a range from 5 to 1000 nm and lengths in range from ten to a thousand microns long. The oxide nanowires can grow vertically in array form on a variety of substrates at high densities of nucleation (10⁷-10¹¹/cm²) and as two dimensional mats at low densities (<10⁷) of nucleation. The synthesis can be performed at various substrate temperatures ranging from 400° C. to 1300° C. Metal filaments or foils or powders or metal containing precursors can be used as the source of the metal.

The crystalline metal oxide nanostructures are comprised of tungsten oxide, titanium dioxide, tantalum oxide, copper oxide, nickel oxide, iron oxides and molybdenum oxides. Tungsten oxide nanowires synthesis can be performed at temperatures ranging from 500° C. to 1000° C. Substrates like fluorinated tin oxide (FTO) and amorphous quartz were used for the synthesis. Synthesis temperatures for tantalum oxide nanowire synthesis range from 800° C. to 1200° C. and for nickel oxides the range is from 1000° C. to 1400° C. The gas phase comprises oxygen or air diluted in a noble gas (Ar, He) or plasma containing oxygen diluted in noble gases. The transition metals are selected from the group consisting of W, Mo, Fe, Ta, Ti, and Cu.

The crystalline metal nanostructures comprise metals such as tungsten, molybdenum, copper, nickel, cobalt, and iron. The synthesis temperature for the case of tungsten metal nanowires using chemical vapor transport of tungsten oxide varies from 1500-2000° C. Nucleation densities as high as 10⁸-10⁹/cm² can be achieved. Metal filaments or foils or powders or the metal containing gas phase precursors can be used as the source of the metal, in a gas phase comprising either oxygen or halogen and hydrogen. Variety of substrates including amorphous quartz, sapphire and boron nitride can be used for the synthesis.

The gas phase can be oxygen or air diluted in a noble gas (Ar, He) and hydrogen or plasma containing oxygen, hydrogen or water vapor diluted in noble gases. In the case of hydrogen, the substrate temperatures could be anywhere between 350 and 2000° C. The gas phase comprising a halogen and hydrogen can be diluted in a noble gas (Ar, He). In the case of halides, synthesis temperatures could be anywhere from 200-1000° C. Tungsten nanowires synthesis could be performed at temperatures, as low as 500° C. using chloride chemical vapor transport. Chemical vapor transport of metal chlorides can be employed for the synthesis of tantalum nanowires and iron nanowires at temperatures as low as 210° C. and 310° C., respectively. The composition of tungsten oxynitride nanowires can be tuned during synthesis by conducting the process and introducing ammonia into the gas phase.

The present invention also provides a means for tuning the bandgap of tungsten oxide nanowires by nitriding using ammonia at temperatures ranging from 400-900° C. and using microwave plasma containing nitrogen and hydrogen at pressures ranging from few mTorr—atmosphere and temperatures ranging from 100° C. till 900° C. The tungsten oxynitride nanowires will be useful for absorbing solar light and will find a tremendous set of applications in photoelectrochemical solar cells and photodetectors.

The process involves the steps comprising rapid dissolution of a solute in a dissolution media comprising a metal forming a film on a substrate, placing the combination in a low-pressure chamber; adding gaseous reactant; applying energy to raise the temperature in the chamber to a point above the melting point of the metal; activating and decomposing the gas phase to yield growth precursors and exposing the molten metal film to the activated gas phase; forming multiple nuclei surfacing out of said molten low-melting metal film; and basal growing of nuclei in one dimension forming nanometer size wires of the desired length.

Moreover, the process also involves a method of synthesizing crystalline metal oxide nanowires from noncatalytic low melting metals, comprises the steps of placing a noncatalytic low-melting metal on a substrate in a low pressure chamber, simultaneously exposing said noncatalytic low melting metal to a microwave plasma containing a selected gaseous reactant in a gas phase heated to a temperature above the melting point of said low-melting metal forming a molten low-melting metal on said substrate and exposing said molten low-melting metal to a sufficient amount of said gaseous reactant in said gas phase for forming a metal oxide, forming multiple nucleations and growing noncatalytic low melting metal oxide nanostructures directly therefrom creating crystalline metal oxide nanowires devoid of any structural defects.

It is an object of the present invention to utilize the direct synthesis approach involving transition and refractory metals providing a technique without using any foreign metal contamination and for working at lower temperatures than those required for traditional catalyst-assisted and physical evaporation methods.

It is another object of the present invention to promote a method of nucleation and growth of metal oxides at temperatures higher than the oxide decomposition temperatures to form metal nanowires.

It is another object of the present invention to provide a method of bulk synthesis of tungsten nanowires.

It is another object of the present invention to provide a method for chemical vapor transport of tungsten oxide above decomposition temperatures (˜1450° C.) for metallic tungsten nanowires.

It is another object of the present invention to provide a method for tungsten metal nanowires at reduced temperatures as low as 100° C. using reducing species in the gas phase.

It is another objective of the present invention to develop a reasonable method for the synthesis of metal oxides of refractory and transition metal oxide nanowires.

It is another objective to develop a non-template method for the bulk synthesis of metal nanowires.

It is another objective of the present invention to develop a scale up reactor design for bulk production of these nanowires.

It is another objective of the present invention to develop a method to overcome the limitation of nanowires growth in the form of bundles and perpendicular alignment to the substrate.

It is another objective of the present invention to synthesize nanowires in a random fashion to achieve better dispersability.

It is another objective of the present invention to develop a method to tune the bandgap of the metal oxide nanowires to cover the wider range of the solar spectrum for photoelectrochemical applications.

Other objects, features, and advantages of the invention will be apparent with the following detailed description taken in conjunction with the accompanying drawings showing a preferred embodiment of the invention.

### BRIEF DESCRIPTION OF THE DRAWINGS

A better understanding of the present invention will be had upon reference to the following description in conjunction with the accompanying drawings in which like numerals refer to like parts throughout the several views and wherein:

FIG. 1 is a scanning electron microscope (SEM) the formation of tapered nanowires in region 2 (FIG. 1 (b)), the formation of straight nanowires in region 3 (FIG. 1 (c)), and FIG. 1 (d) shows a low magnification of a TEM micrograph of a straight nanowire, together with the region on the substrate where the formations are formed;

FIG. 2 is a Transmission Electron Microscope (TEM) microphotograph showing the diffraction patterns from the obtained nanowires wherein region (a) and region (b) show BCC crystal structure corresponding to tungsten where the growth direction is [110], and the XRD pattern of the as-synthesized sample at 1750° C. shows diffraction peaks corresponding to two phases, metallic tungsten from regions 1, 2, and 3 and monoclinic tungsten trioxide from region 4;

FIG. 3 shows a schematic representation of the reactor setup used for the synthesis of metal and metal oxide nanowires;

FIG. 4 shows SEM images of the synthesized tungsten oxide nanowires;

FIG. 5 shows SEM images of the synthesized tungsten oxide nanowire arrays;

FIG. 6 shows the variation of nucleation densities of nanowires using substrate temperature and partial pressure of oxygen as parameters;

FIG. 7 shows the XRD pattern and Raman spectra of synthesized tungsten oxide nanowire arrays;

FIG. 8 shows electron micrographs and Raman spectra of synthesized Ta₂O₅ nanowires;

FIG. 9 shows electron micrographs of Fe nanowires;

FIG. 10 shows electron micrographs and Raman spectrum of synthesized NiO nanowires;

FIG. 11 shows electron micrographs of tungsten nanowires;

FIG. 12 shows a schematic representation of the pre pilot scale hot walled reactor setup; and

FIG. 13 shows a pictorial representation of the pre pilot scale hot walled reactor setup.

### DETAILED DESCRIPTION OF THE PREFERRED EMBODIMENT

Nucleation and growth of metal oxides at temperatures higher than the oxide decomposition temperatures has resulted in the bulk synthesis of metal nanowires, more particularly, tungsten nanowires. The chemical vapor transport of tungsten in the presence of oxygen onto substrates kept at temperatures higher than the tungsten oxide decomposition temperature (1450° C.) led to nucleation and growth of pure metallic tungsten nanowires.

The synthesis of metal and metal oxide nanowires of metals, especially refractory metals are formed via a novel vapor phase. Chemical vapor phase transport and nucleation of metal oxides onto substrates maintained at a temperature of 800° C., leads to the formation of the respective metal oxides, followed by in-situ reduction using hydrogen, leads to the formation of the respective metal nanowires. The diameter of the nanowires can be controlled using temperature as a parameter. Nucleation densities as high as 10¹¹/cm² can be achieved using this method.

A pre-pilot scale modified HF-CVD hot walled reactor was set up to synthesize bulk quantities of the above-mentioned metal and metal oxide nanowires. Currently, the amount of nanowires synthesized is limited by the substrate area available. The hot walled reactor setup built overcomes this limitation and allows bulk synthesis of these nanowires. The reactor assembly consists of a 2 inch diameter quartz tube set inside a high temperature oven (Max. Temp.=1500° C., over a 9 inch length). The quartz tube is equipped with electrical feed-through, gas inlets, pressure measurement devices, and a vacuum pump. A metal filament heated using electrical power serves as the source material for the synthesis of metal and metal oxide nanowires. This set up allows for the production of gram quantities of nanowires per day. Nanowire arrays on a variety of substrates including quartz, Fluorinated Tin Oxide (FTO) substrates etc. were synthesized without any furnace heating. This avoided the requirement of a constant substrate heating using the furnace and dramatically reduced the total time needed for the synthesis.

The chemical vapor transport experiments were performed using the modified HF-CVD reactor in which substrates were placed close to the filaments (0.5 mm diam) at a distance of 1 mm or less. O₂ flow rate has varied from 0.03 to 0.1 sccm in 90 sccm of either N₂ or Ar. Experiments were performed at different filament temperatures ranging from 1200 to 2000° C. and at a pressure of 150 mTorr.

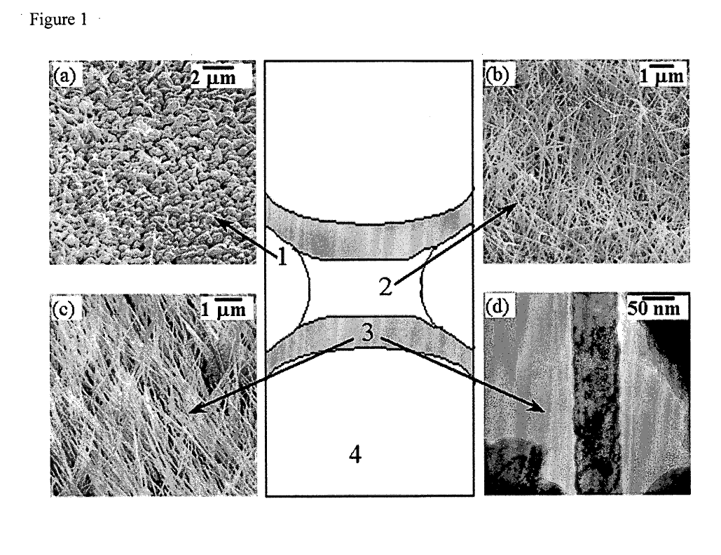

The scanning electron micrographs of the tungsten nanowires resulting from the chemical vapor transport of tungsten from tungsten filaments at a temperature of 1750° C. with 0.03 sccm of O2 in 90 sccm of N₂ are shown in FIG. 1. The tungsten filament made contact with the substrate at the edges of region 1. The regions (a few millimeters on either side of the filament) closest to filament showed high densities of nanowires. In region 1(a) which is very close (<1 mm) to the filament, crystals of tungsten are observed as depicted in FIG. 1(a). The formation of tapered nanowires are shown in region 2(b), the formation of straight nanowires are shown in region 3(c), and region 3(d) shows a low magnification of a TEM micrograph of a straight nanowire. FIG. 1 also shows the regions on the substrate where the formations are formed.

In some instances, the tungsten nanowires joined together and appeared as a sheet like structures, as seen at a few places in FIG. 1c. Region 4, which is farther away from the filament on the substrate, exhibited nanocrystalline tungsten oxide deposit. The diameter of the resulting nanowires ranged from 55 nm at a filament temperature of 1750° C. to as low as 40 nm at 2000° C. and are a few micrometers longer. The resulting density of the nanowires was approximately 10⁸-10⁹/cm². The results did not show any dependence on the substrate use, that is, pBN or quartz, indicating no role of substrate material on the growth of nanowires.

A low magnification TEM image (FIG. 1d) indicates no tapering of the nanowires found in region 3. The majority of the nanowires without any apparent tapering at the end and without any cluster at the tip.

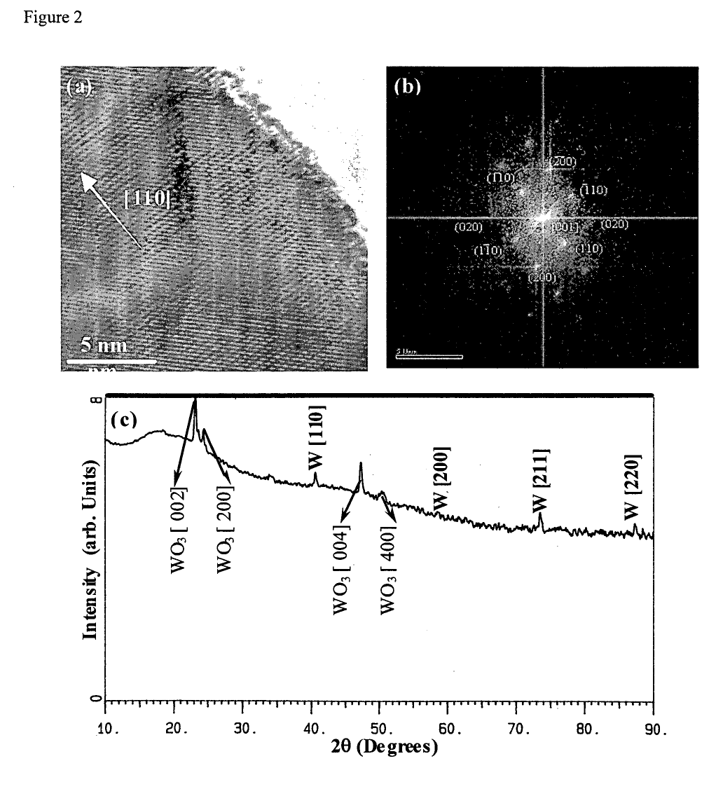

A high resolution TEM (FIG. 2a) indicates that the nanowires are a single crystalline with no amorphous or oxide sheath at the edges and that the growth direction is [110] (FIG. 2b). The XRD pattern (FIG. 2c) of the as-synthesized sample at 1750° C. shows diffraction peaks corresponding to two phases, metallic tungsten from regions 1, 2, and 3 and monoclinic tungsten trioxide from region 4.

The chemical vapor transport experiments onto substrates at a temperature of 1250° C. produced only polycrystalline tungsten trioxide according to XRD and SEM analysis. This indicates that the growth of tungsten nanowires occur by the decomposition of the already formed tungsten trioxide to tungsten, which is considered as a necessary step for 1-D growth during the process. Experiments conducted by placing a second substrate at a distance around 5-8 mm from the filament formed both tungsten trioxide nanowires and nanotubes. No tungsten nanowires were formed on the substrate. The temperature of this substrate, heated primarily by radiation, is 800° C. Initial analysis of this sample using XRD and TEM showed the presence of monoclinic WO₃ nanowires and nanotubes.

It is believed that the nucleation and growth of tungsten nanowires occurs by the following mechanism. The WO₂ vapor phase species is formed in the presence of oxygen. Nucleation of WO₂ on the substrate occurs due to supersaturation of WO₂ (v) in the gas phase. For condensation of the vapor phase species, the critical nuclei diameter, d_{c}, depends on the supersaturation by the relation
d_{c}=4σ?/[RTln(p/p*)]
where σ is the interfacial energy, ? is the molar volume, T is the temperature of the substrate, p is the partial pressure of the growth species, and p* is the vapor pressure of the growth species at equilibrium. Both p and p* are functions of temperature. As the filament temperature increases, the supply of the participating vapor phase species, that is, p, increases along with the increase in p*.

The analysis using the thermodynamic data from NASA database suggests that the formation of WO₂(v) species is quite spontaneous.
W+O₂⇄WO₂(v)

Similarly, tungsten trioxide vapor phase species could also be formed simultaneously. Yet, the gas-solid equilibrium calculations in the presence of tungsten oxide solid phases indicate that tungsten dioxide is the primary vapor phase species. The condensation of the tungsten dioxide species takes place both in the nucleation stages and in the further growth process as adatoms. The adatoms undergo subsequent decomposition to tungsten at high temperatures (closer to the filament).
WO₂(v)⇄W(s)+O₂
WO₃(v)⇄W(s)+ 3/2O₂

The growth in one-dimension is accomplished by the preferential condensation of tungsten oxide on preexisting tungsten oxide at the tip of the nanowire and the subsequent decomposition of tungsten oxide to tungsten. At high temperatures (very close to the filament), the net rate of decomposition is higher than the rate of condensation, giving rise to the tapering observed in nanowires found in region 2 of FIG. 1b. Similarly, at slightly lower temperatures (slightly away from the filament), but higher than the decomposition temperature, the net rate of decomposition is similar to the rate of condensation, allowing. uniform diameter shown in FIG. 1(c). When the substrate temperature is maintained at a temperature lower than the decomposition temperature of the tungsten oxide, 1-D growth of tungsten oxide nanowires will occur. The 1-D growth of tungsten oxide occurs due to the preferential condensation of the tungsten oxide nuclei followed by subsequent addition of tungsten oxide adatoms on the preexisting nuclei. The subsequent oxidation of these adatoms to WO_{2.9}(S) and WO₃(S) is assumed to occur leading to the growth of tungsten oxide nanowires. The following are the oxidation reactions of the adatoms at the substrate maintained below the decomposition temperature of the tungsten oxide which are spontaneous.
WO₂₍ₛ₎+½O_{2(g)}→WO₃₍ₛ₎
WO₂₍ₛ₎+0.45O_{2(g)}→WO_{2.9(s)}

The vapor phase technique in which condensation of oxide species are heated above their decomposition temperatures leads to the growth of metal nanowires. Increasing temperatures beyond the decomposition temperature reduced the diameter of the nanowires. This technique may be extended to the synthesis of other metal nanowires and their oxides including tungsten, iron, tantalum, niobium, copper, nickel, molybdenum, titanium, vanadium, chromium, manganese, yttrium, zirconium, ruthenium, rhodium, osmium, iridium, and palladium.

The present example provides a novel vapor phase concept for the synthesis of metal and metal oxide nanowires of metals, especially refractory metals. Chemical vapor phase transport and nucleation of metal oxides onto substrates maintained at a temperature of 800° C., leads to the formation of the respective metal oxides, followed by in-situ reduction using hydrogen, leads to the formation of the respective metal nanowires. The diameter of the nanowires can be controlled using temperature as a parameter. The present invention provides a means for producing nanowires at temperature as low as 100° C. by using hydrogen along with oxygen.

Moreover, the invention provides for a method of synthesizing bulk quantities of oxide nanostructures of non-catalytic, low melting metals, comprising the steps of exposing molten non-catalytic, low melting metals to an activated gas phase, for example plasma, containing an appropriate mixture of oxygen and hydrogen radicals. Multiple nuclei are formed that grow in one dimension directly there from creating highly crystalline metal oxide nanowires devoid of any structural defects having thicknesses in a range from 20 to 100 nm and lengths in range from ten to a thousand microns long.

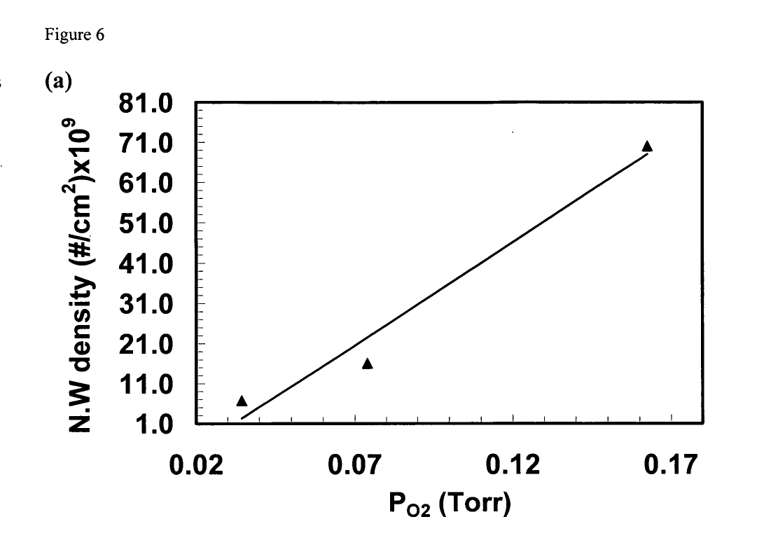

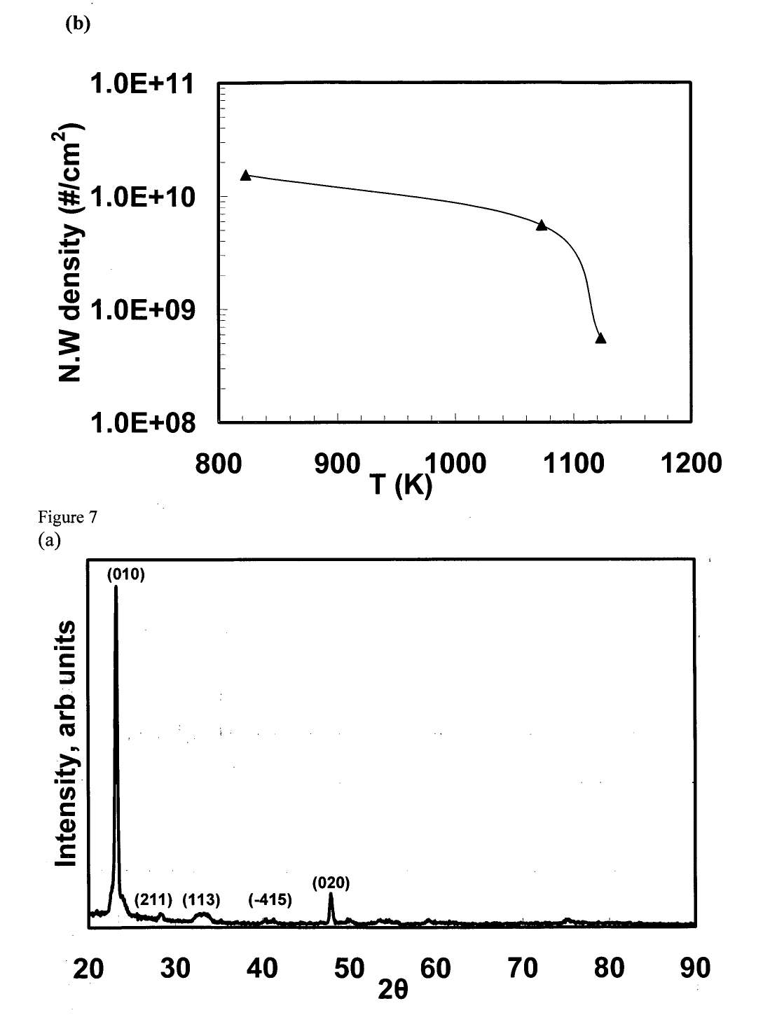

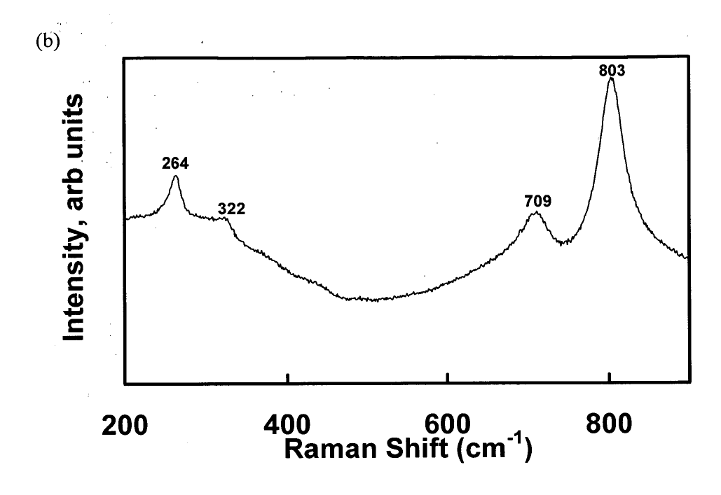

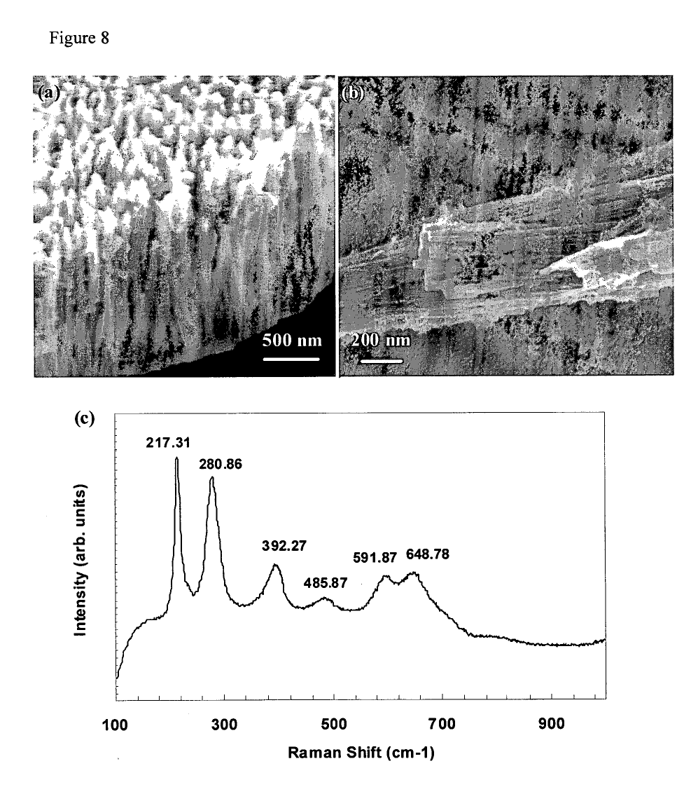

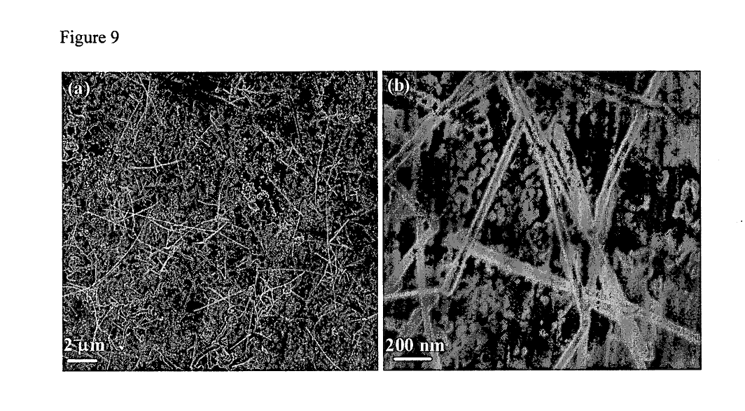

Chemical vapor phase transport and nucleation of metal oxides onto substrates maintained at a temperature of 800° C., leads to the formation of the respective metal oxide nanowires. The diameter of the nanowires can be controlled using temperature and partial pressure of oxygen as parameters. The variation of nanowire density with partial pressure of oxygen and temperature is presented in FIG. 6.

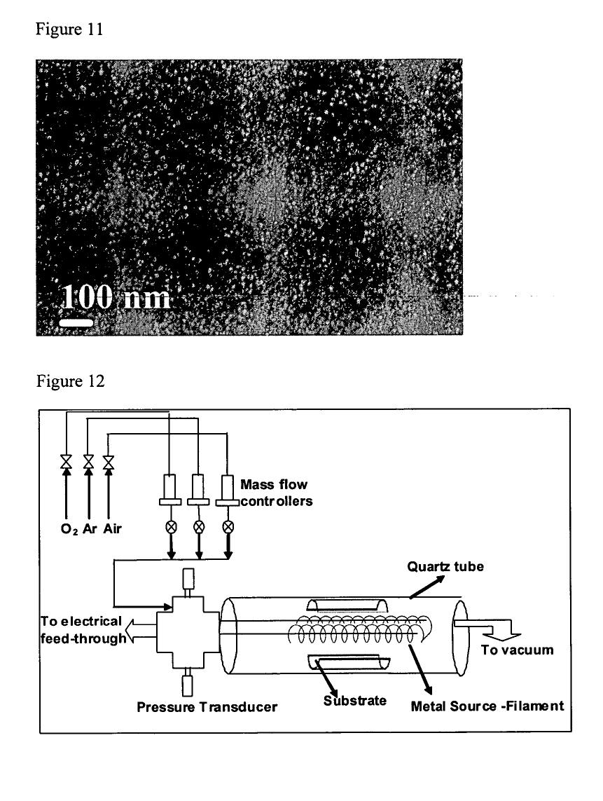

Tungsten nanowires were also synthesized by bubbling ammonium hydroxide using an argon gas. Presence of hydrogen radicals led to the formation of tungsten nanowires in a similar mechanism as proposed. Uniform deposition of tungsten nanowires are shown in FIG. 11.

Process Scale-up for Bulk Production of Nanowires

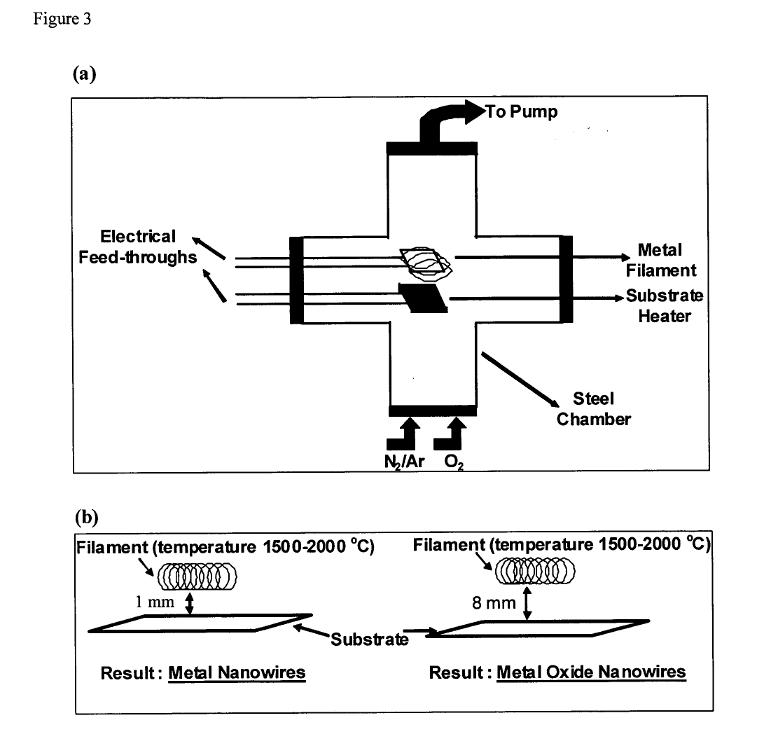

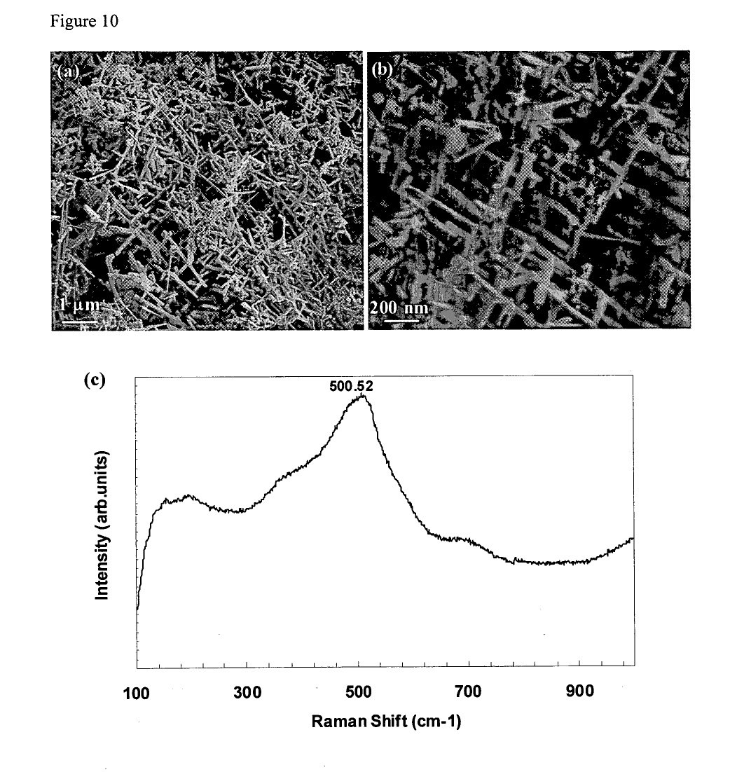

As best shown in FIGS. 3 and 10, pre pilot scale hot walled reactor was set up to synthesize bulk quantities of the above-mentioned metal and metal oxide nanowires. Currently, the amount of nanowires synthesized is limited by the substrate area available. The hot walled reactor setup built overcomes this limitation and allows bulk synthesis of these nanowires. The reactor assembly consists of a 2 inch diameter quartz tube set inside a high temperature oven (Max. Temp.=1500° C., over a nine inch length). The quartz tube is equipped with electrical feed-through, gas inlets, pressure measurement devices, and a vacuum pump. A metal filament heated using electrical power serves as the source material for the synthesis of metal and metal oxide nanowires. This set up allows for the production of gram quantities of nanowires per day.

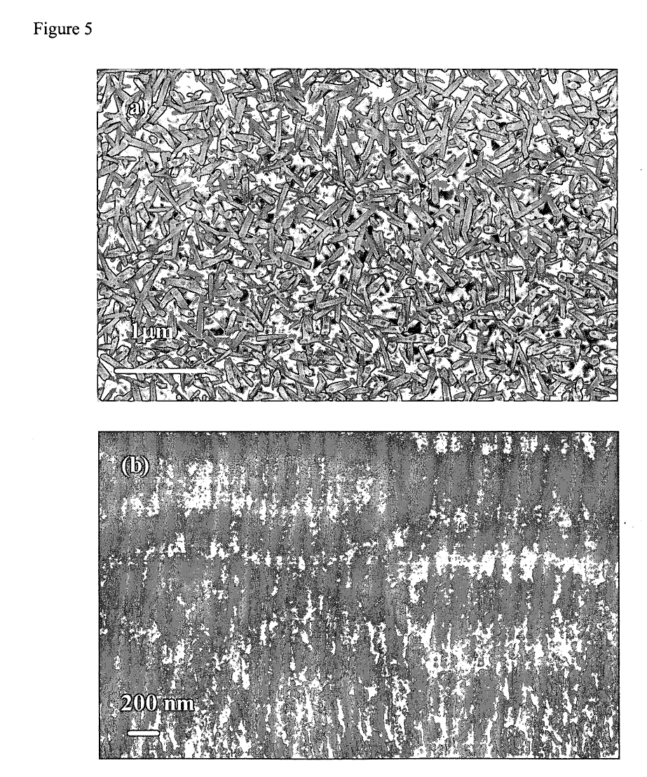

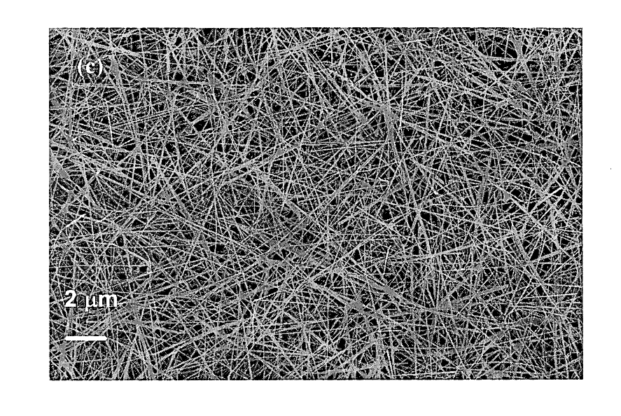

In this setup, nanowire arrays can be synthesized on large number of conducting substrates like Fluorinated Tin Oxide (FTO) in a single run. As shown in FIG. 5, all the tungsten oxide nanowires are vertically oriented with diameters in the range of 40 to 70 nm in diameter and micron scale length. These as-synthesized nanowire arrays on FTO substrates are presently being used for electrochromic applications. In this particular reactor setup, nanowires can be obtained in the form of dry powder by just scrapping from the substrates and is presently being used for nanowire dispersion applications.

Application of the Nanowires in Dispersion

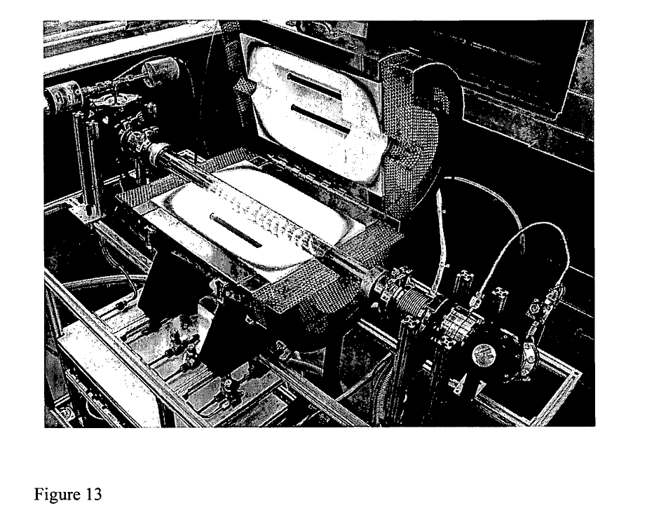

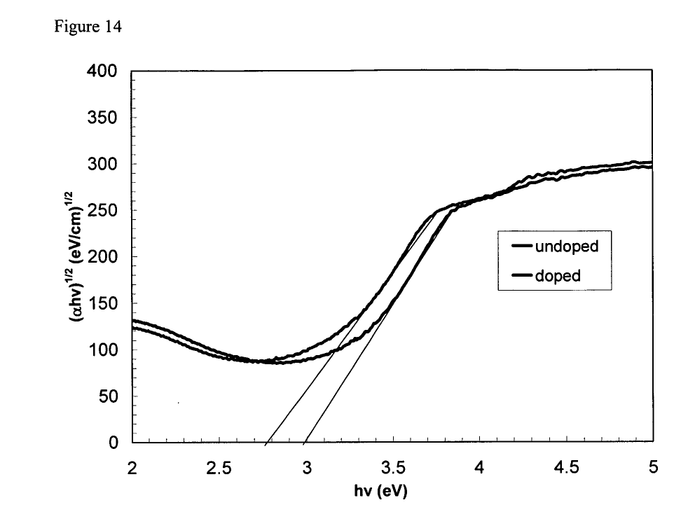

The dispersability of metal oxide nanoparticles in solvent, like ethanol, is crucial for their use in various applications (photochromic and electrochromic applications). Currently, tedious process techniques, like functionalization of the particles, are being employed to obtain a homogeneous and stable dispersion. The instant invention reveals that metal oxides in the form of nanowires form stable homogeneous dispersions, compared to, nanoparticles of the same material as shown in FIG. 13.

Band Gap Tuning of As-synthesized Tungsten Oxide Nanowires

The doping of the nanowires is crucial for use in photoelectrochemical applications. The as-synthesized tungsten oxide nanowires were doped with nitrogen in nitrogen plasma (750 watts) in a micro-wave reactor for about 30 minutes. The initial invention shows the bandgap tuning of the nanowires by doping with nitrogen. As shown in FIG. 14, the doped nanowires show a band gap reduction from 3.0 to 2.8 eV.

Synthesis Procedure

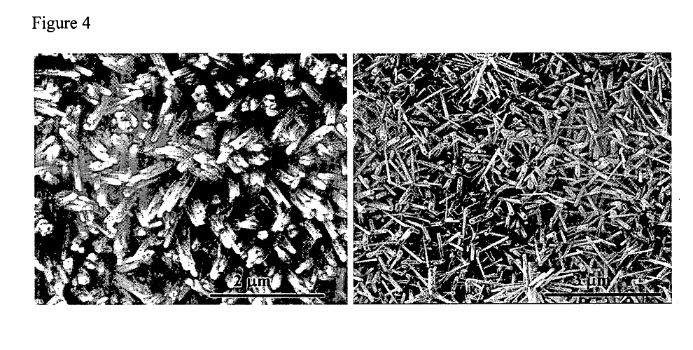

A hot filament chemical vapor deposition reactor equipped with a metal filament was used for purpose of making the respective metal and metal oxide nanowires. Tungsten, tantalum and iron filaments were used for the synthesis of the respective metal oxide nanowires as shown in FIGS. 4&5. A quartz piece placed at a distance of approximately 5 mm from the filament, served as the substrate for the synthesis of metal oxide nanowires. The filament was maintained at a temperature of 1000-2000° C. The temperature of the substrate, primarily heated by radiation, is approximately 800° C. Oxygen varying in concentrations from 0.03-0.1 sccm diluted in 100-300 sccm of Argon was used for the vapor transport experiments. Hydrogen varying in concentrations from 1-2 sccm was added to the gas phase for the synthesis of metal nanowires. These experiments were performed at various pressures ranging from 60 mTorr to 5 Torr. Various experimental conditions used fore the synthesis of metal and metal oxide nanowires are presented in Table 1. After approximately 2 hours, a deposit was observed on the surface of the substrate. The deposit was characterized using scanning electron microscopy (SEM), x-ray diffraction (XRD) and high-resolution transmission electron microscopy (HRTEM).

TABLE 1
Experimental conditions employed for the synthesis of various transition metal and metal
oxide nanowires using chemical vapor transport

| Nanowire | Filament | | Substrate | | | | |
|---|---|---|---|---|---|---|---|
| Material | temperature, ° C. | | temperature, ° C. | | O₂ Flow rate | Pressure | |
| Tungsten (w) | 1500-2000° | C. | 1500-2000° | C. | 0.01-0.03 sccm | 150 | mTorr |
| | | | | | diluted in 100 | | |
| | | | | | sccm of Ar/N₂ | | |
| Iron (Fe) | 1450° | C. | 1450° | C. | 0.4 sccm | 40 | mTorr |
| | | | | | diluted in 2 | | |
| | | | | | sccm of H₂ | | |
| Tungsten oxide | 2000° | C. | 800° | C. | 0.01-0.03 sccm | 150 | mTorr |
| (WO₃) | | | | | diluted in 100 | | |
| | | | | | sccm of Ar/N₂ | | |
| Tantalum | 2000° | C. | 800° | C. | 0.4 sccm | 2-5 | Torr |
| pentoxide | | | | | diluted in 100 | | |
| (Ta₂O₅) | | | | | sccm of Ar | | |
| Nickel Oxide | 1350° | C. | 1350° | C. | 1 sccm diluted | 150 | mTorr |
| (NiO) | | | | | in 100 sccm of | | |
| | | | | | Ar | | |

A vapor phase technique has been demonstrated in which condensation of oxide species above their decomposition temperatures leads to growth of metal nanowires in accordance with FIGS. 12. Increasing temperature beyond the decomposition temperature reduced the diameter of the nanowire. This technique may be extended to the synthesis of other metal nanowires such as Fe, Ta, Ti, Cu, etc set forth heretofor.

In the Pre-pilot scale hot walled hot filament rector setup, tungsten oxide nanowires in the form of arrays and mats were synthesized. Tungsten oxide nanowires in the form of mats were synthesized at a flow rate of 0.08 sccm O₂ in presence of 100 sccm of Ar. Under these conditions, the filament was heated to a temperature of 1950° K. and the substrate was maintained at 800° C. Nanowires in the form of arrays were synthesized without any uniform substrate heating. In this particular case, the substrate was heated due to the radiation from the filament maintained at a temperature of about 1950° K. under flow rates of 2.3 sccm of O₂. This process provided us to synthesize nanowires on conducting substrates like FTO which would otherwise melt when the substrate is heated to a temperature of 800° C.

The foregoing detailed description is given primarily for clearness of understanding and no unnecessary limitations are to be understood therefrom, for modifications will become obvious to those skilled in the art based upon more recent disclosures and may be made without departing from the spirit of the invention and scope of the appended claims.

1. A method of synthesizing oxide nanostructures of non-catalytic, low melting metals, comprising the steps of:
chemical vapor transport of oxide or halide or metalorganic vapor phase species using either liquid or gas or solid sources onto substrates kept at temperatures lower than the decomposition temperatures of the respective oxides; and
forming a high density of nuclei that grow in one dimension directly creating highly crystalline metal oxide nanowires devoid of any structural defects and having diameters in a range from 5 to 1000 nm and lengths in range from ten to a thousand microns long. The oxide nanowires could grow vertically in array form on a variety of substrates at high densities of nucleation (10⁷-10¹¹/cm²) and as two dimensional mats at low densities (<10⁷) of nucleation. The synthesis could be performed at various substrate temperatures ranging from 400° C. to 1300° C. Metal filaments or foils or powders or metal containing precursors can be used as the source of the metal.

2. The method of synthesizing oxide nanostructures of transition metals of claim 1, wherein said crystalline metal oxide nanostructures comprise of tungsten oxide, titanium dioxide, tantalum oxide, copper oxide, nickel oxide, iron oxides and molybdenum oxides.

3. The method of synthesizing oxide nanostructures of transition metals of claim 1, wherein said gas phase comprises of oxygen or Air diluted in a noble gas (Ar, He) or plasma containing oxygen diluted in noble gases.
